(19) United States
(12) Patent Application Publication
(10) Pub. No.: US 2021/0109159 A1
(43) Pub. Date: Apr. 15, 2021

(54) BATTERY IMPEDANCE MEASUREMENT CIRCUITS AND METHODS THEREOF

(71) Applicant: NXP B.V., Eindhoven (NL)

(72) Inventor: Joop Petrus Maria van Lammeren, Beuningen (NL)

(21) Appl. No.: 16/599,860

(22) Filed: Oct. 11, 2019

(51) Int. Cl. G01R 31/36; G01R 31/389; G01R 31/392; G01R 31/3842; G07C 5/02

(52) U.S. Cl. CPC G01R 31/3644; G01R 31/389; B60L 58/12; G01R 31/3842; G07C 5/02; G01R 31/392

(57) ABSTRACT

An example circuit includes synchronous demodulator circuitry, analog-to-digital converter (ADC) circuitry, and window circuitry. The synchronous demodulator circuitry measures impedance of a battery at a target frequency based on generated excitation waveforms. The ADC circuitry to produce digital representations of a power parameter responsive to application of at least one of the generated excitation waveforms to the battery. The window circuitry generates weighted outputs of the digital representations of the power parameter using a window function. And the synchronous demodulator circuitry further measure the impedance using the digital representations of the power parameter, the generated excitation waveforms, and the window function.

Aspects of various embodiments are directed to a circuit for measuring impedance of a battery.

Impedance measurements of rechargeable batteries may be used in variety of applications. For example, in electric and/or hybrid vehicles, battery management of the rechargeable batteries may benefit from impedance measurements. In many rechargeable battery applications, large numbers of series-connected battery cells are used to generate a voltage for driving components, such as a vehicle motor. Managing the state of health and state of charge of the series-connected battery cells can be performed using information obtained by the impedance measurements.

These and other matters have presented challenges to efficiencies of battery impedance measurement implementations, for a variety of applications.

### SUMMARY

Various example embodiments are directed to issues such as those addressed above and/or others which may become apparent from the following disclosure concerning measuring impedance of a battery.

In certain example embodiments, aspects of the present disclosure involve a circuit that measures impedance of a battery forming part of a vehicle, in which the impedance measurements are obtained while the vehicle is moving and drive current is drawn from the battery by an electric motor of the vehicle.

In a more specific example embodiment, a circuit includes synchronous demodulator circuitry, analog-to-digital converter (ADC) circuitry, and window circuitry. The synchronous demodulator circuitry measures impedance of a battery at a target frequency based on generated excitation waveforms. The ADC circuitry produces digital representations of a power parameter responsive to application of at least one of the generated excitation waveforms to the battery. The power parameter includes one of voltage, current, impedance, and combinations thereof. The window circuitry generates weighted outputs of the digital representations of the power parameter using a window function. The synchronous demodulator circuit further measures the impedance using the digital representations of the power parameter, the generated excitation waveforms, and the window function. The circuit may form part of a vehicle having the battery, and the window circuitry is to generate the weighted outputs to mitigate interference and an effect of changes in direct current on the measured impedance obtained by the synchronous demodulator circuitry while the vehicle is moving. The at least one of the generated excitation waveforms may be applied to the battery in addition to current drawn from the battery by a load (e.g., drive current drawn from the battery by an electric motor).

In various embodiments, the window circuitry includes a counter circuit, a memory circuit, and a multiplier circuit. The counter circuit provides values for the window function and the multiplier circuit multiplies the digital representations of the power parameter by the values of the window function and, thereby, generates the weighted outputs. The memory circuit provides multiplication factors based on the values for the window function, and the multiplier circuit generates a product of the digital representations of the power parameter and the multiplication factors, and thereby, generates the weighted outputs. In other embodiments, the window circuitry may include the counter circuit and multiplier circuit, without a memory circuit. The counter circuit provides values for the window function and the multiplier circuit multiplies the digital representations of the power parameter by the values of the window function and, thereby, generates the weighted outputs.

The window circuitry generates the weighted outputs using a triangular window function, in some specific embodiments. For example, the target frequency includes even frequencies responsive to the target frequency being below a threshold, and the window circuitry is to generate the weighted outputs using a triangular window function. The target frequency includes even and odd frequencies responsive to the target frequency being above the threshold. However, embodiments are not so limited, and the window circuit may use a variety of window functions to generate the weighted outputs, such as a triangular window function, a Dirichlet window function, a Parzen window function, a Blackman-Nuttall window function, a Welch window function, a Hann window function, and various other functions.

The synchronous demodulator circuitry may include a wave circuit to generate the excitation waveforms at one target frequency per measurement and a synchronous demodulator. The wave circuit generates the excitation waveforms including generating sample values indicative of a sine waveform and a cosine waveform at the single target frequency. The wave circuit further outputs one of the sine and cosine waveforms to generate current input to the battery and to identify a real component of the power parameter, and outputs the other of the sine and cosine waveforms to identify an imaginary component of the power parameter. The synchronous demodulator circuitry, e.g., the synchronous demodulator, includes first and second multiplier circuits and first and second integrator circuits. The first multiplier circuit and first integrator circuit multiply one of the sine and cosine waveforms by the weighted outputs of the digital representations indicative of the power parameter to identify the real component. The second multiplier circuit and a second integrator circuit multiply the other of the sine and cosine waveforms by the weighted outputs of the digital representations of the power parameter to identify the imaginary component.

In more specific embodiments, the ADC circuitry includes a low pass filter circuit to provide the digital representations of the power parameter below a threshold frequency. The circuit further includes a digital-to-analog converter circuit to produce analog representations of at a least a portion of the generated excitation waveforms, the analog representations being indicative of current to input to the battery. The input current may be proportional to the generated excitation waveforms.

In another specific example embodiment, a method includes generating excitation waveforms at a target frequency using a wave circuit, producing digital representations of power parameters responsive to application of at least one of the generated excitation waveforms to a battery, generating weighted outputs of the digital representations of the power parameter using a window function, and measuring impedance of the battery using the digital representations of the power parameter, the generated excitation waveforms, and the window function. The generation of the excitation waveforms can be at one target frequency per measurement.

As described above, generating the weighted outputs mitigates interference and an effect of changes in direct current on the measured impedance obtained by the synchronous demodulator circuit while the vehicle is moving and/or when the vehicle is standing still and charging. In specific embodiments, the measurement of the impedance of the battery using the digital representations indicative of the power parameter, the generated excitation waveforms, and the window function occurs while a vehicle operating the battery is moving. For example, the method may further include applying at least one of the generated excitation waveforms to the battery in addition to drive current drawn by a load of the battery, the load including an electric motor.

In various embodiments, generating weighted outputs of the digital representations of the power parameter using the window function further includes providing, by a counter circuit, values for the window function, providing multiplication factors based on the values for the window function, and multiplying the digital representations of the power parameter by the multiplication factors to generate the weighted outputs. In other embodiments, generating weighted outputs of the digital representations of the power parameter using the window function further includes providing, by a counter circuit, values for the window function, and multiplying the digital representations of the power parameter by the values of the window function to generate the weighted outputs.

The above discussion/summary is not intended to describe each embodiment or every implementation of the present disclosure. The figures and detailed description that follow also exemplify various embodiments.

### BRIEF DESCRIPTION OF FIGURES

Various example embodiments may be more completely understood in consideration of the following detailed description in connection with the accompanying drawings, in which:

FIG. 1 illustrates an example circuit for measuring impedance of a battery, in accordance with the present disclosure;

FIG. 2 illustrates another example circuit for measuring impedance of a battery, in accordance with the present disclosure; and

FIGS. 3A-3C are graphs illustrating example effects of circuits for measuring impedance of a battery, in accordance with the present disclosure.

While various embodiments discussed herein are amenable to modifications and alternative forms, aspects thereof have been shown by way of example in the drawings and will be described in detail. It should be understood, however, that the intention is not to limit the disclosure to the particular embodiments described. On the contrary, the intention is to cover all modifications, equivalents, and alternatives falling within the scope of the disclosure including aspects defined in the claims. In addition, the term “example” as used throughout this application is only by way of illustration, and not limitation.

### DETAILED DESCRIPTION

Aspects of the present disclosure are believed to be applicable to a variety of different types of apparatuses, systems and methods involving measuring impedance of a battery, such as a battery being used to drive an electric motor. In certain implementations, aspects of the present disclosure have been shown to be beneficial when used in the context of obtaining the impedance measurements while the vehicle is moving and drive current is drawn from the battery by an electric motor of the vehicle. While not necessarily so limited, various aspects may be appreciated through the following discussion of non-limiting examples which use exemplary contexts.

Accordingly, in the following description various specific details are set forth to describe specific examples presented herein. It should be apparent to one skilled in the art, however, that one or more other examples and/or variations of these examples may be practiced without all the specific details given below. In other instances, well known features have not been described in detail so as not to obscure the description of the examples herein. For ease of illustration, the same reference numerals may be used in different diagrams to refer to the same elements or additional instances of the same element. Also, although aspects and features may in some cases be described in individual figures, it will be appreciated that features from one figure or embodiment can be combined with features of another figure or embodiment even though the combination is not explicitly shown or explicitly described as a combination.

Impedance measurements may be used for battery management for a variety of applications. For example, impedance measurements may be used to estimate or determine the state of health (SOH) and/or state of charge (SOC) of a rechargeable battery. While the SOC is not generally derived directly from impedance, knowledge of SOH may improve SOC estimation, particularly as the battery cells age and/or have been through numerous charge and discharge cycles. The impedance measurements may be used to determine a condition of the battery and/or individual battery cells and for controlling the charge of the cells. For vehicle applications, impedance measurements are obtained while the vehicle is at rest and while moving, and which may be used to determine a temperature of the battery and/or individual cells of the battery. The behavior of the battery cell may depend on the corresponding temperature. Impedance measurements while the vehicle is at rest may be affected by the noise of the integrated circuit (IC). When the vehicle is moving, there may be interference from the electric motor and an effect of direct current (DC) current on the measurement. For example, the DC current flow varies due to changes in acceleration and/or braking of the vehicle, and which impacts the voltage on the battery throughout the measurement.

To measure impedance of a battery, an electrochemical impedance spectroscopy (EIS) technique may be used that determines the impedance of the battery at different frequencies. In various embodiments, one frequency is measured at a time and multiple measurements are made over a range of frequencies. A source drives current through the battery, such as a current and/or voltage source that drives a current or voltage through a battery cell at a low amplitude. The source (e.g., voltage or current source) may be under control of the impedance measurement circuit or outside the control, such as the drive current of a traction motor of an electric vehicle while the vehicle is operating and/or moving, as further described herein. The current is converted into voltage by a resistor connected in series with the battery and a band-pass filter eliminates unwanted signals before providing to amplitude and phase meters, which measure the battery voltage and voltage across a conversion resistor. Real and imaginary components of the impedance of the battery are determined from the amplitude and phase information of the measured voltages as indicated by:

$$\vert {z}_{bat} \vert = \frac{{V}_{bat}}{{V}_{conv}} {R}_{conv}$$

$$R {e}_{bat} = \vert {z}_{bat} \vert \times cos ( {ϕ}_{bat} )$$

$${Im}_{bat} = \vert {z}_{bat} \vert \times sin ( {ϕ}_{bat} )$$

with the phase of the voltage across R_{conv} being defined as zero.

Example embodiments are directed to an impedance measurement circuit that obtains impedance measurements for a battery being used to drive current of a motor of a vehicle. The impedance measurements may be made while the vehicle is moving. The circuit includes synchronous demodulator circuitry, analog-to-digital converter (ADC) circuitry, and window circuitry. The synchronous demodulator circuitry measures impedance of the battery at a target frequency based on generated excitation waveforms. In specific embodiments, the synchronous demodulator circuitry includes a wave circuit that generates the excitation waveforms and is used to apply at least one of the excitation waveforms to the battery and a synchronous demodulator. More specifically, one of a sine and a cosine waveform (e.g., a small signal) is added (e.g., injected) to current drawn by a load of the battery, such as the drive current drawn by the electric motor of a vehicle. The sine waveform or cosine waveform is smaller relative to the current drawn by the load. The ADC circuitry produces digital representations of a power parameter (e.g., voltage and/or current) response to the application of the at least one of the generated excitation waveforms to the battery. The window circuitry generates weighted outputs of the digital representations of the power parameter using a window function. By using the window function during impedance measurements and while the vehicle is moving, noise and/or the effect of varying DC current on the impedance measurement may be mitigated and/or removed. The synchronous demodulator circuitry, via the synchronous demodulator, measures the impedance using the digital representations of the power parameter, the generated excitation waveforms, and the window function. For example, the synchronous demodulator uses both the sine and cosine waveforms and the weighted outputs of the digital representations of the power parameter to provide an indication of the impedance.

In various embodiments, the window circuitry includes a counter circuit, a memory circuit, and a multiplier circuit. The counter circuit provides values for the window function, the memory circuit provides multiplication factors based on the values for the window function, and the multiplier circuit generates a product of the digital representations of the power parameter and the multiplication factors, and thereby, generates the weighted outputs. In other embodiments, the window circuitry includes a counter circuit and multiplier circuit, and may not include a memory circuit. The counter circuit provides values for the window function and the multiplier circuit multiplies the digital representations of the power parameter by the values of the window function and, thereby, generates the weighted outputs.

In specific embodiments, the window circuitry generates the weighted outputs using a triangular window function. For example, the target frequency includes even frequencies responsive to the target frequency being below a threshold, and the window circuitry is to generate the weighted outputs using a triangular window function. The target frequency includes even and odd frequencies responsive to the target frequency being above the threshold. However, embodiments are not so limited, and the window circuit may use a variety of other window functions to generate the weighted outputs. As used herein, even and odd frequencies include or relate to the integer number of cycles of the target frequency in the measurement window.

In various embodiments, the impedance measurements may be used for detecting temperature characteristics of battery cells. For example, impedance behavior of the cell in the frequency domain is monitored and used to provide an indication of temperature. This behavior may be monitored over time, and used to characterize temperature characteristics as the battery cell ages. Certain embodiments are directed to controlling the operation of such cells based upon the temperature characteristics, as generally and specifically described by U.S. Publ. No. 2013/0314049, entitled “Battery Cell Temperature Detection” and filed on Jul. 23, 2012. As described by the U.S. Publ. No. 2013/0314049, the intercept frequency of an imaginary component of the measured impedance is used to estimate cell temperatures (e.g., without necessarily obtaining and/or using an entire Nyquist plot). Cell impedance is detected at two or more frequencies, and used to determine or otherwise detect an intercept frequency at which an imaginary component of a detected impedance is about zero (at a zero crossing point), which is indicative of an actual (real) frequency. In some embodiments, interpolation is used with the two points to approximate a zero crossing point. In certain embodiments, the cell impedance is measured at a first (e.g., arbitrary) frequency. If the imaginary component of the impedance is positive, then impedance is detected at a higher frequency. If the imaginary component of the impedance is negative impedance is detected at a lower frequency. This procedure is repeated until the imaginary component of the impedance is (nearly) zero.

In accordance with a number of embodiments, it may be beneficial to obtain impedance measurements in the range of 10-100 Hertz (Hz), among other ranges, and which are used to assess the internal temperature of a battery being operated by a vehicle and while the vehicle is moving. The change of impedance may be higher in the range of 10-100 Hz, as compared to ranges above 1 kHz. Circuits in accordance with the present disclosure may remove noise caused by the electric motor and mitigate the effect of varying DC current.

For general information regarding battery cells, and for specific information regarding manners in which individual cell impedances can be measured in a long chain of series-connected cells, reference may be made to each of the following, all of which are fully incorporated herein by reference: Hong, Y-J. et al. “Modeling of the Thermal Behavior of a Lithium-Ion Battery Pack”, Advanced Automotive Battery Conference, 4 pgs. (2010); U.S. Publication No. 2012/0010507, entitled “Spectroscopic Battery-Cell-Impedance Measurement Arrangement for Large Battery Packs Using the Cell Balancing Current”; U.S. Pat. No. 9,128,165, entitled “Method to Measure the Impedances of Battery Cells in a (H)EV Application”, filed May 4, 2011; and U.S. application Ser. No. 13/150,959, “DFT-Based Battery-Cell-impedance Measurement Arrangement for High-Voltage Battery Packs”.

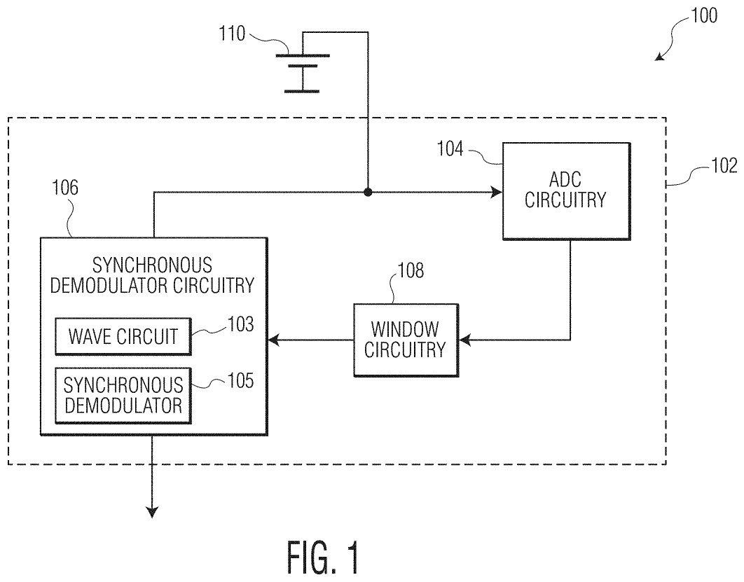

Turning now to the figures, FIG. 1 illustrates an example circuit for measuring impedance of a battery, in accordance with the present disclosure. The circuit 100 may include an impedance measurement circuit 102 used to measure impedance of the battery 110. In specific examples, the circuit 102 forms part of a vehicle and is used to measure impedance while the vehicle is moving and/or at rest. As further described herein, the impedance measurement circuit 102 includes synchronous demodulator circuitry 106, ADC circuitry 104, and window circuitry 108.

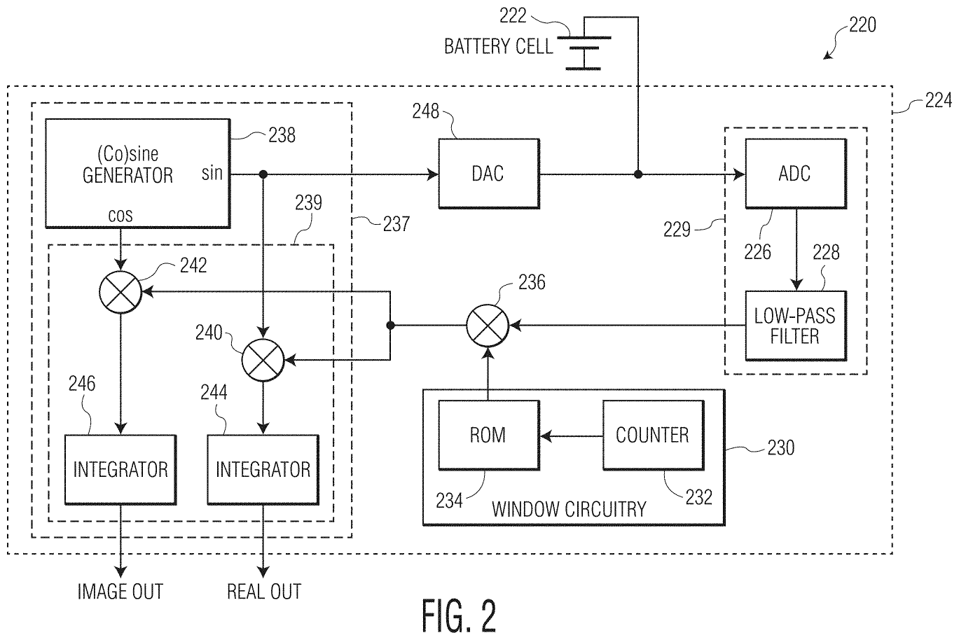

The synchronous demodulator circuitry 106 may measure impedance of a battery 110 at a target frequency based on generated excitation waveforms. The synchronous demodulator circuitry 106 measures the real and imaginary components of a power parameter, such as impedance, at one frequency per measurement. The synchronous demodulator circuitry 106 may be interchangeably referred to as a single point Fast Fourier transform (FFT) circuit. In various embodiments, as further illustrated by FIG. 2, the synchronous demodulator circuitry 106 includes a synchronous demodulator 105 and a wave circuit 103.

The wave circuit 103, which is sometimes herein referred to as a “co(sine) generator”, generates excitation waveforms. The excitation waveforms include sample values indicative of a sine waveform and a cosine waveform at the target frequency. In specific embodiments, the synchronous demodulator circuitry 106 generates the excitation waveforms at one target frequency per measurement. The synchronous demodulator circuitry 106, via the synchronous demodulator 105, measures the impedance using the digital representations of the power parameter, the generated excitation waveforms, and the window function. The synchronous demodulator circuitry 106 may output one of the sine and cosine waveforms to generate current input to the battery 110 and to identify a real component of the power parameter, and outputs the other of the sine and cosine waveforms to identify an imaginary component of the power parameter. In various specific embodiments, the at least one of the generated excitation waveforms is applied to the battery 110 in addition to current drawn from the battery 110 by a load.

The wave circuit 103, e.g., the co(sine) generator, may control the input of current into the battery 110 by providing a modulated signal (e.g., a pulse-density modulation (PDM) modulated signal), with the modulation set to input or modulate current at a desired (signal) frequency. A variety of (co)sine generators can be implemented in connection with these and other embodiments. For general information regarding such generators, and for specific information regarding generators that may be implemented in connection with these embodiments, reference may be made to U.S. application Ser. No. 13/100,652, entitled “Method to measure the impedances of battery cells in a (H)EV application”, and filed on May 4, 2011, which is fully incorporated herein by reference. A current is input (e.g., injected and/or modulated) to the battery 110 that has a density proportional to the amplitude of the excitation waveform. One of the sine and cosine waveforms may be applied to the battery 110 in addition to current drawn by a load of the battery 110. The current drawn by a load may be modulated with the known waveform. The current drawn may include drive current drawn by an electric motor of a vehicle and/or while the vehicle is moving, with the sine or cosine waveform being added to the current drawn. For example, the sine or cosine waveforms is injected to the battery 110 (e.g., a cell of the battery 110) with the current drawn, and the injected sine or cosine waveform is smaller than the current drawn. A voltage is produced across a battery cell as a result of the current input, which is measured.

Although not illustrated, the circuit 100 may further include or be in communication with a control circuit which may control the frequency and the amplitude of the excitation waves. Additionally, a voltage and/or current source may be used for inputting current to the battery. The source may be under control of the impedance measurement circuit 102 (e.g., the co(sine) generator circuit) or outside direct control of the impedance measurement circuit 102, such as via drive current of an electric motor of a vehicle employing the battery 110 as described above. When implemented in a vehicle, the impedance measurement circuit 102 can be used while the vehicle is at rest using the source under control of the impedance measurement circuit 102 and while the vehicle is moving using the drive current. Further, battery impedance may be measured at any frequency at any time.

Accordingly, while the above describes modulating the current drawn from the battery by a load, embodiments may additionally include injection of current, such as injecting current when the vehicle is not moving. Similarly, the excitation waveform used to input current may be the cosine waveform, rather than the sine waveform. In specific examples, the impedance measurement circuit 102 further includes a current injection circuit to inject current based on the generated excitement wave from the synchronous demodulator circuitry 106. The current injection circuit may control the injection frequencies in conjunction with the control circuit and/or the wave circuit 103, such as when a vehicle implementing the circuit 102 is at rest. The current injection circuit is operated to inject current into the battery 110 at different frequencies. In specific examples, current is injected using the excitement wave which is controlled by the control circuit that sets the frequency and the amplitude of the injected current and uses time stamp data.

In various examples, the control circuit sends commands to the synchronous demodulator circuitry 106 to set the frequency and amplitude of the generated excitement wave for input current and/or modulation of the drawn current. The synchronous demodulator circuitry 106 may provide one of the sine wave and the cosine wave for generating the input current and the real component of the power parameter, and provide the other of the sine wave and the cosine wave for generating the imaginary component. Time stamp information and information regarding the amplitude and frequency of the excitation waveforms and the input current may be used to determine impedance.

The synchronous demodulator circuitry 106 may drive the battery using one frequency at a time, with memory storing data corresponding to the frequencies. The measurements may be made over a range of frequencies, using one frequency at a time. Various techniques for calculating the impedance and the resulting temperature may be used, such as described by US Publication No. 2013/0314049, entitled “Battery Cell Temperature Detection” and filed on Jul. 23, 2012; and US Publication No. 2012/0306504, entitled “Battery Impedance Detection System, Apparatus, and Method”, filed Jun. 1, 2011, which are fully incorporated herein by reference.

Values of components that generate the input current into the battery 110 may be used as inputs regarding the current, without necessarily using a current meter. With this information and the voltage (or other power parameter) of the battery 110, such as a battery cell being tested, for which impedance is to be measured, the value of the current that is injected or modulated into the battery 110 can be calculated.

The ADC circuitry 104 may be used to measure the voltage and/or other power parameter of the battery and provide a digitized version of the power parameter. For example, the ADC circuitry 104 produce digital representations of the power parameter responsive to application of the generated excitation waveform to the battery 110. The power parameter includes voltage, current, impedance, and/or combinations thereof. The ADC circuitry 104 may include an ADC and a low pass filter. The ADC measures cell voltage, in response to the input current. The low pass filter may filter the output of the ADC to provide digital representations of the power parameter below a threshold frequency. In specific embodiments, each digitized voltage generated by the ADC circuitry 104 is separated into real and imaginary components or parts by multiplier circuits of the synchronous demodulator circuitry 106.

As described above, the impedance measurement circuit 102 may be implemented in a vehicle and provides impedance measurements of the battery 110 while the vehicle is being operated, such as while the vehicle is moving. The window circuitry 108 generates weighted outputs of the digital representations of the power parameter as provided by the ADC circuitry 104 using a window function. For example, the window circuitry 108 generates the weighted outputs to mitigate interference and an effect of changes in DC on the measured impedance obtained by the synchronous demodulator circuitry 106 while the vehicle is moving.

In accordance with various embodiments, the window circuitry 108 may include a counter circuit to provide values (e.g., windows) for the window function, and a multiplier circuit to multiply the digital representations of the power parameter by the values of the window function and, thereby, generate the weighted outputs. In specific embodiments, the window circuitry 108 further includes a memory circuit to provide multiplication factors based on the values for the window function. In such embodiments, the multiplier circuit generates a product of the digital representations of the power parameter and the multiplication factors, and therefrom, generates the weighted outputs.

A variety of window functions may be used. For example, the window circuitry 108 may generate the weighted outputs using one of a triangular window function, a Dirichlet window function, a Parzen window function, a Blackman-Nuttall window function, a Welch window function, and a Hann window function, among other window functions. When a triangular window function is used, the target frequency may include even frequencies (and discount odd frequencies) responsive to the target frequency being below a threshold, and the window circuitry 108 generates the weighted outputs using the triangular window function.

In specific embodiments, a Blackman-Nuttall window function is used. With a Blackman-Nuttall window function (or other types of functions), the window circuitry 108 may additionally include a memory circuit, such as read-only memory (ROM), to accommodate the multiplication factors of the Blackman-Nuttall window function. In other examples, the triangular function may be used and may provide a performance that is similar to the Blackman-Nuttall window function for frequencies above around 30 Hz. For frequencies below 30 Hz (for a measurement window of one second), with a triangular window function, the odd frequencies may not be used as the performance is comparable to the triangular window function for even frequencies but is not for odd frequencies (e.g., by the wave circuit of the synchronous demodulator circuitry 106 that generates the sine and cosine waveforms). For frequencies above 30 Hz, even and odd frequencies are used (e.g., by the wave circuit). Embodiments are not limited to a threshold of 30 Hz and may include other thresholds such as 100 Hz and/or to a memory circuit being used with a Blackman-Nuttall window function. For example, the window circuitry 108 implementing a window function other than a Blackman-Nuttall window function may include the above-described memory circuit.

In other specific embodiments, a triangular window function can be implemented by a 15-bit up/down counter circuit and a multiplier circuit. When a new measurement slice starts, the counter counts from 0 and counts up to 2\hat{ }15−1. The counter circuit then switches to count down mode and goes from 2\hat{ }15−1 to 0. Note that the value 2\hat{ }15−1 is used twice in the middle of the measurement slice. When the counter circuit is back to 0, the measurement slice is finished, as there are 2\hat{ }16 low-pass filter output samples in one measurement slice.

For a variety of window functions, a counter circuit may be used to generate the address for a memory circuit (e.g., a ROM) that contains the multiplication factors. As the addresses of a triangular window are equal to the multiplication factor, the triangular window does not need a ROM. It therefore has the lowest cost of the possible window functions.

By adding a window function to the impedance measurement circuit 102, embodiments in accordance with the present disclosure allow for impedance measurement to gauge the internal temperature of each battery cell in a vehicle battery pack, while the vehicle is driving. The window allows for use of low measurement frequencies (e.g., less than 100 Hz), where the change of impedance with temperature is higher than at frequencies that are greater than 1 kHz. In specific examples, a triangular window function is used, and its non-idealities can be mitigated or avoided by using only the even frequencies for measurements at frequencies below 30 Hz, and by using by using both the odd and even frequencies for measurements at frequencies at or above 30 Hz.

The synchronous demodulator 105 of the synchronous demodulator circuitry 106 measures the impedance using the digital representations indicative of the power parameter, the generated excitation waveforms, and the window function. For example, the weighted outputs from the window circuitry 108, which are the digitized voltage generated by the ADC circuitry 104 as multiplied by the window function, are separated into real and imaginary components by multiplier circuits of the synchronous demodulator 105. More specifically, multiplier circuits are used to multiply the weighted outputs by a corresponding sample of the sine and cosine waveforms as provided by the wave circuit 103 of the synchronous demodulator circuitry 106. The real component is identified by multiplying the weighted outputs by the waveform (sine or cosine) generated by the wave circuit 103 and used to modulate and/or create the input current in the battery 110 that results in the particular power parameter measurement. The imaginary component is identified by multiplying the weighted outputs by the other of the waveforms (cosine or sine) generated by the wave circuit 103 (and not used to create the current).

The real and imaginary components may be accumulated, such as by integrator circuits of the synchronous demodulator circuitry 106, for one more periods of time. The real and imaginary components of the impedance may be a result of the accumulations.

FIG. 2 illustrates another example circuit for measuring impedance of a battery, in accordance with the present disclosure. The circuit 220 illustrated by FIG. 2 may include an impedance measurement circuit 224, such as the impedance measurement circuit 102 illustrated by FIG. 1, and a battery 222.

The impedance measurement circuit 224 is used to provide impedance measurements of the battery 222. The impedance measurement circuit 224 includes synchronous demodulator circuitry 237 that includes a synchronous demodulator 239 and the co(sine) generator 238, sometimes herein interchangeably referred to as “a wave circuit”. The co(sine) generator 238 generates the excitation waveforms at one target frequency per impedance measurement, and may be used to obtain measurements over a range of frequencies. The excitation waveforms include a sine waveform and cosine waveform at the single target frequency, with one of the sine waveform and the cosine waveform being used to input current into the battery 222. In the specific example of FIG. 2, the sine waveform is used to input current into the battery 222, although examples are not so limited and the cosine waveform may be used.

The impedance measurement circuit 224 may further include a digital-to-analog converter (DAC) circuit 248. The DAC circuit 248 produces analog representations of at least a portion of the generated excitation waveforms, such as the sine waveform used in the specific example to input current to the battery 222. The analog representations are indicative of current to input to the battery, the input current being proportional to the generated excitation waveforms (e.g., amplitude is proportional to the sine wave form or the cosine waveform).

The ADC circuitry 229 is used to produce the digital representations of the power parameter responsive to the application of the generated excitation waveform (e.g., the modulated and/or injected current based on the sinewave form) to the battery 222. The ADC circuitry 229 includes an ADC 226 and a low-pass filter 228, as previous discussed. As may be appreciated, depending on the type of ADC 226 used, a low-pass filter may not be included in circuit 220, in accordance with various embodiments.

The window circuitry 230 generates weighted outputs of the digital representations of the power parameter using a window function, as previously described. The window circuitry 230 includes a counter circuit 232 and a multiplier circuit 236. Although the multiplier circuit 236 is illustrated as separate from the window circuitry 230, the multiplier circuit 236 may be part of or separate from the window circuitry 230. In specific embodiments, the window circuitry 230 further includes a memory circuit 234. However, as previously described embodiments are not so limited and the window circuitry 230 which implements a triangular window function may not include or use a memory circuit 234.

The synchronous demodulator 239 of the synchronous demodulator circuitry 237 measures the impedance of the battery 222 using the digital representations of the power parameter, the generated excitation waveforms, and the window function. The co(sine) generator 238 may output one of the sine and cosine waveforms (e.g., the sine waveform) to generate current input to the battery 222 (e.g., added to the current drawn by the load of the battery 222) and to identify a real component of the power parameter, and outputs the other of the sine and cosine waveforms (e.g., the cosine waveform) to identify an imaginary component of the power parameter.

In specific embodiments, the synchronous demodulator 239 includes a first multiplier circuit 240, a second multiplier circuit 242, a first integrator circuit 244 and a second integrator circuit. The first multiplier circuit 240 and a first integrator circuit 244 multiply the one of the sine and cosine waveforms (e.g., sine waveform) by the weighted outputs of the digital representations indicative of the power parameter to identify the real component of the power parameter. The second multiplier circuit 242 and the second integrator circuit 246 multiply the other of the sine and cosine waveforms (e.g., the cosine waveform) by the weighted outputs of the digital representations of the power parameter to identify the imaginary component of the power parameter. The first and second integrator circuits 244, 246 may capture results across a frequency range at different measurement times.

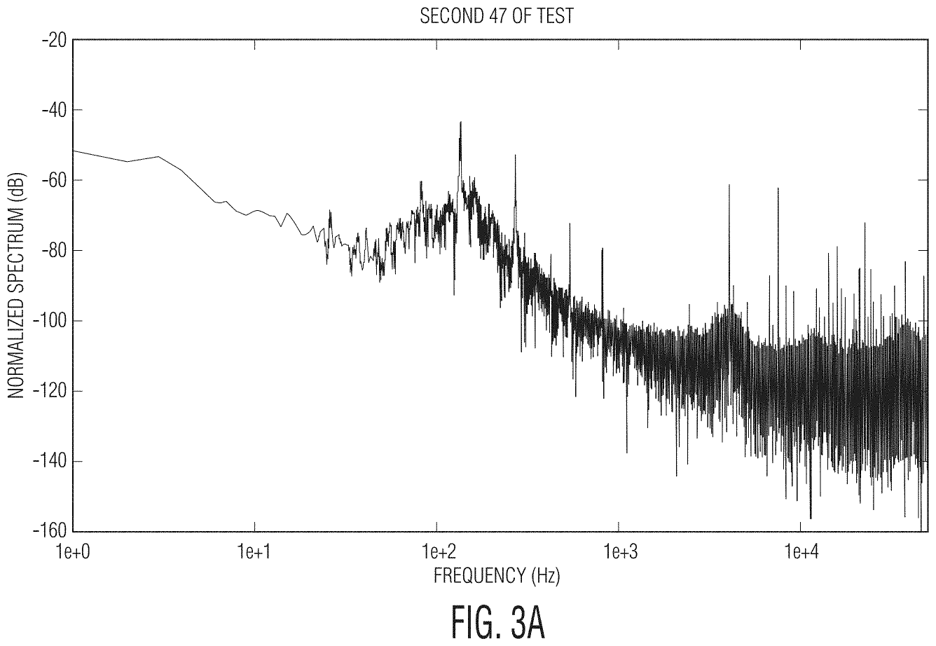

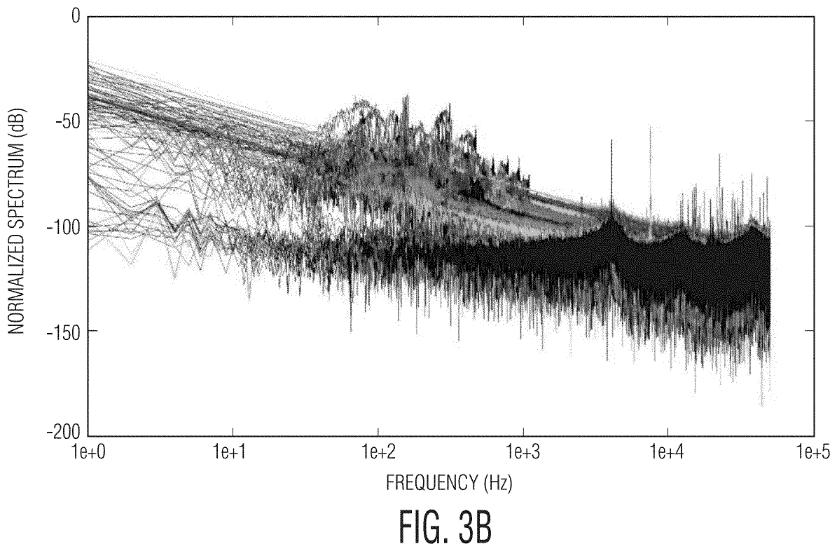

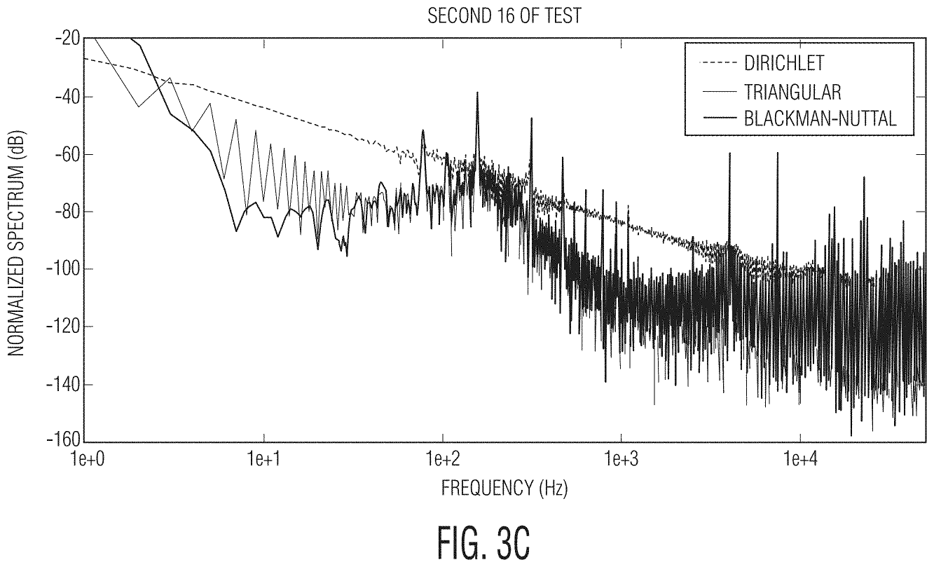

FIGS. 3A-3C are graphs illustrating example effects of circuits for measuring impedance of a battery, in accordance with the present disclosure. As previously described, when obtaining impedance measurements of a battery while the vehicle is running, the electric motor may cause interference and changes in DC current due to driving phases (e.g., the user accelerating and/or braking) which may result in changes in the voltage on the battery cell over the measurement interval.

FIG. 3A is a graph illustrating example noise caused by the electric motor. More specifically, a spectrum is illustrated by FIG. 3A of one measurement interval (e.g., one second). During the measurement interval, the vehicle is driving and no window function is used. The effect of the DC current drawn by the electric motor of the vehicle can be seen in the roughly −6 dB/octave slope at the low frequency end. FIG. 3B is a graph illustrating the spectra of 120 measurement intervals without a window function. In some intervals, the spectrum is very low for all frequencies. During these intervals, the vehicle is standing still. During other intervals, there is a strong low-frequency response with a 20 db/octave roll-off. During these intervals, the vehicle is moving. The 20 dB/octave roll-off is caused by the DC current drawn by the motor. At low frequencies, the effect of this DC current can be so high that it overwhelms the frequencies that are present in the spectrum.

FIG. 3C is a graph illustrating example performance of different window functions on one measurement interval. More specifically illustrated is a Dirichlet window function, a Blackman-Nuttall window function, and a triangular window function.

The Dirichlet window (e.g., the same as using no window) shows a 20 dB/decade rolloff from low to high frequencies. At low frequencies, there is a strong spurious signal, which is caused (only) by the DC difference of the beginning and the end of the measurement interval. The Blackman-Nuttall window suppresses the spurious signal by roughly 40 dB for frequencies higher than 8 Hz. The triangular window shows a better performance than the Dirichlet window for all frequencies. The triangular window shows a performance similar to the Blackman-Nuttall window for even frequencies. For odd frequencies up to about 30 Hz, the suppression is less.

With the triangular window function, for frequencies below 30 Hz, even frequencies are used and odd frequencies may be discarded. As previously described, the triangular window function can be implemented by a 15-bit up/down counter circuit and a multiplier circuit, such as shown by FIG. 2.

For many window functions, a counter circuit is used to generate the address for the memory circuit (e.g., the ROM) that contains the multiplication factors. As the address of a triangular window is equal to the multiplication factor, the window circuit that uses a triangular window may not include or use a ROM. The triangular window may therefore have the lowest cost of all possible windows. For example, with a Blackman-Nuttall window function, it is estimated that the rough estimate the ROM uses 2\hat{ }15 addresses of 23 bits.

The above-described circuits can be used to implement a variety of methods. An example method includes generating excitation waveforms at a target frequency using a wave circuit, producing digital representations of a power parameter responsive to application of at least one of the generated excitation waveforms to a battery, generating weighted outputs of the digital representations of the power parameter using a window function, and measuring impedance of the battery using the digital representations of the power parameter, the generated excitation waveforms, and the window function. The generation of the excitation waveforms can be at one target frequency per measurement.

As described above, generating the weighted outputs mitigates interference and an effect of changes in direct current on the measured impedance obtained by the synchronous demodulator circuit while the vehicle is moving. In specific embodiments, the measurement of the impedance of the battery using the digital representations of the power parameter, the generated excitation waveforms, and the window function occurs while a vehicle operating the battery is moving. For example, the method may further include applying the at least one of generated excitation waveforms to the battery in addition to drive current drawn by a load of the battery, the load including an electric motor.

In various embodiments, generating weighted outputs of the digital representations of the power parameter using the window function further includes providing, by a counter circuit, values for the window function, and multiplying the digital representations of the power parameter by the values of the window function to generate the weighted outputs. In other embodiments, generating weighted outputs of the digital representations of the power parameter using the window function further includes providing, by a counter circuit, values for the window function, providing multiplication factors based on the values for the window function, and multiplying the digital representations of the power parameter by the multiplication factors to generate the weighted outputs.

Terms to exemplify orientation, such as upper/lower, left/right, top/bottom and above/below, may be used herein to refer to relative positions of elements as shown in the figures. It should be understood that the terminology is used for notational convenience only and that in actual use the disclosed structures may be oriented different from the orientation shown in the figures. Thus, the terms should not be construed in a limiting manner.

The skilled artisan would recognize that various terminology as used in the Specification (including claims) connote a plain meaning in the art unless otherwise indicated. As examples, the Specification describes and/or illustrates aspects useful for implementing the claimed disclosure by way of various circuits or circuitry which may be illustrated as or using terms such as blocks, modules, device, system, unit, controller and/or other circuit-type depictions. Such circuits/circuitry are used together with other elements to exemplify how certain embodiments may be carried out in the form or structures, steps, functions, operations, activities, etc. For example, in the above-discussed embodiments, one or more modules are discrete logic circuits or programmable logic circuits configured and arranged for implementing these operations/activities, as may be carried out in the approaches shown herein. In certain embodiments, such a programmable circuit is one or more computer circuits, including memory circuitry for storing and accessing a program to be executed as a set (or sets) of instructions (and/or to be used as configuration data to define how the programmable circuit is to perform), and an algorithm or process as described herein is used by the programmable circuit to perform the related steps, functions, operations, activities, etc. Depending on the application, the instructions (and/or configuration data) can be configured for implementation in logic circuitry, with the instructions (whether characterized in the form of object code, firmware or software) stored in and accessible from a memory (circuit). As another example, where the Specification may make reference to a “first multiplier”, a “second multiplier”, etc., where the multiplier might be replaced with terms such as “circuit”, “circuitry” and others, the adjectives “first” and “second” are not used to connote any description of the structure or to provide any substantive meaning; rather, such adjectives are merely used for English-language antecedence to differentiate one such similarly-named structure from another similarly-named structure (e.g., “first multiplier to multiply . . . ” is interpreted as “circuit to multiply . . . ”).

Based upon the above discussion and illustrations, those skilled in the art will readily recognize that various modifications and changes may be made to the various embodiments without strictly following the exemplary embodiments and applications illustrated and described herein. For example, methods as exemplified in the Figures may involve steps carried out in various orders, with one or more aspects of the embodiments herein retained, or may involve fewer or more steps. For example, the circuits illustrated by FIGS. 1 and 2 may be used to implement the methods described herein. Such modifications do not depart from the true spirit and scope of various aspects of the disclosure, including aspects set forth in the claims.

What is claimed is:

1. A circuit comprising:
synchronous demodulator circuitry to measure impedance of a battery at a target frequency based on generated excitation waveforms;
analog-to-digital converter (ADC) circuitry to produce digital representations of a power parameter responsive to application of at least one of the generated excitation waveforms to the battery; and
window circuitry to generate weighted outputs of the digital representations of the power parameter using a window function,
wherein the synchronous demodulator circuit is to measure the impedance using the digital representations of the power parameter, the generated excitation waveforms, and the window function.

2. The circuit of claim 1, wherein the circuit forms part of a vehicle having the battery, and the window circuitry is to generate the weighted outputs to mitigate interference and an effect of changes in direct current on the measured impedance obtained by the synchronous demodulator circuitry while the vehicle is moving.

3. The circuit of claim 1, wherein the synchronous demodulator circuitry includes a wave circuit to generate the excitation waveforms at one target frequency per measurement.

4. The circuit of claim 1, wherein the window circuitry includes:
a counter circuit to provide values for the window function; and
a multiplier circuit to multiply the digital representations of the power parameter by the values of the window function and, thereby, generate the weighted outputs.

5. The circuit of claim 1, wherein the window circuitry includes:
a counter circuit to provide values for the window function;
a memory circuit to provide multiplication factors based on the values for the window function; and
a multiplier circuit to generate a product of the digital representations of the power parameter and the multiplication factors, and thereby, generate the weighted outputs.

6. The circuit of claim 1, wherein the window circuitry is to generate the weighted outputs using a triangular window function.

7. The circuit of claim 1, wherein the target frequency includes even frequencies responsive to the target frequency being below a threshold, and the window circuitry is to generate the weighted outputs using a triangular window function.

8. The circuit of claim 7, wherein the target frequency includes even and odd frequencies responsive to the target frequency being above the threshold.

9. The circuit of claim 1, wherein:
the window circuitry is to generate the weighted outputs using one of a triangular window function, a Dirichlet window function, a Parzen window function, a Blackman-Nuttall window function, a Welch window function, and a Hann window function, and
the power parameter includes one of voltage, current, impedance, and combinations thereof.

10. The circuit of claim 1, wherein the synchronous demodulator circuitry includes a wave circuit to generate the excitation waveforms by generating sample values indicative of a sine waveform and a cosine waveform at the target frequency, and to output one of the sine waveform and cosine waveform to generate current input to the battery and to identify a real component of the power parameter, and to output the other of the sine waveform and cosine waveform to identify an imaginary component of the power parameter.

11. The circuit of claim 10, wherein the synchronous demodulator circuitry further includes:
a first multiplier circuit and a first integrator circuit to multiply the one of the sine waveform and cosine waveform by the weighted outputs of the digital representations of the power parameter to identify the real component; and
a second multiplier circuit and a second integrator circuit to multiply the other of the sine waveform and cosine waveform by the weighted outputs of the digital representations of the power parameter to identify the imaginary component.

12. The circuit of claim 1, wherein:
the ADC circuitry includes a low pass filter circuit to provide the digital representations of the power parameter below a threshold frequency; and
the circuit further including a digital-to-analog converter circuit to produce analog representations of at least a portion of the generated excitation waveforms, the analog representations being indicative of current to input to the battery, the input current being proportional to the generated excitation waveforms.

13. The circuit of claim 1, wherein the at least one of the generated excitation waveforms is applied to the battery in addition to current drawn from the battery by a load.

14. A method comprising:
generating excitation waveforms at a target frequency;
producing digital representations of a power parameter responsive to application of at least one of the generated excitation waveforms to a battery;
generating weighted outputs of the digital representations of the power parameter using a window function; and
measuring impedance of the battery using the digital representations of the power parameter, the generated excitation waveforms, and the window function.

15. The method of claim 14, wherein the measuring of the impedance of the battery using the digital representations of the power parameter, the generated excitation waveforms, and the window function occurs while a vehicle operating the battery is moving.

16. The method of claim 14, further including applying the at least one of generated excitation waveforms to the battery in addition to drive current drawn by a load of the battery, the load including an electric motor.

17. The method of claim 14, wherein generating the weighted outputs mitigates interference and an effect of changes in direct current on the measured impedance obtained by synchronous demodulator circuitry while a vehicle operating the battery is moving.

18. The method of claim 14, further including generating the excitation waveforms at one target frequency per measurement.

19. The method of claim 14, wherein generating weighted outputs of the digital representations of the power parameter using the window function further includes:
providing, by a counter circuit, values for the window function; and
multiplying the digital representations of the power parameter by the values of the window function to generate the weighted outputs.

20. The method of claim 14, wherein generating weighted outputs of the digital representations of the power parameter using the window function further includes:
providing, by a counter circuit, values for the window function;
providing multiplication factors based on the values for the window function; and
multiplying the digital representations of the power parameter by the multiplication factors to generate the weighted outputs.
